(19) United States
(12) Patent Application Publication
(10) Pub. No.: US 2009/0260844 A1
(43) Pub. Date: Oct. 22, 2009

(54) WATERPROOF CASING

(75) Inventor: Tien-Chung Tseng, Taipei Hsien (TW)

Correspondence Address: CHOATE, HALL & STEWART LLP, TWO INTERNATIONAL PLACE, BOSTON, MA, 02110, US

(73) Assignee: WISTRON CORPORATION, Taipei Hsien (TW)

(21) Appl. No.: 12/360,395

(22) Filed: Jan. 27, 2009

(30) Foreign Application Priority Data
Apr. 21, 2008 (TW) 097114461

(51) Int. Cl. H05K 5/06

(52) U.S. Cl. 174/50.5

(57) ABSTRACT

A waterproof casing is adapted for enclosing an electronic device therein. The electronic device includes at least one operating portion. The waterproof casing includes a casing unit and at least one pliable transparent film. The casing unit includes first and second casing halves that are coupled together and that cooperatively define an internal receiving space for accommodating the electronic device. The casing unit is formed with at least one opening that corresponds in size and position to the at least one operating portion of the electronic device. The film corresponds in number to the opening, and is connected to a peripheral edge of the opening. The waterproof casing allows a user to press the operating portion through the film when operating the electronic device under water.

### CROSS-REFERENCE TO RELATED APPLICATION

This application claims priority of Taiwanese Application No. 097114461, filed on Apr. 21, 2008, which is incorporated herein by reference in its entirety.

### BACKGROUND OF THE INVENTION

1. Field of the Invention

The invention relates to a waterproof casing, more particularly to a waterproof casing that is adapted for use with an electronic device to enable the electronic device to be operable under water.

2. Description of the Related Art

Some commercially available electronic devices, such as mobile phones, digital cameras, PDAs, etc., have waterproofing functionality and can prevent entry of water thereinto. However, most of the electronic devices do not have any waterproofing functionality. In order that such electronic devices can be resistant to water, a waterproof casing is generally utilized.

Referring to FIG. 1, Taiwanese Utility Model No. M286471 discloses a waterproof casing 1, which includes a first casing half 11 and a second casing half 12. The first and second casing halves 11, 12 are coupled by means of complementary grooves and insert walls, and cooperatively define an internal chamber 13. An electronic device (not shown) may be housed in the internal chamber 13 of the waterproof casing 1, and is therefore waterproofed.

However, when a user needs to operate a touch screen and buttons or controls on the electronic device, since the waterproof casing 1 is formed from a rigid material, it is not possible for the user to operate the touch screen and the buttons through the waterproof casing 1 to operate the electronic device within the waterproof casing 1. The electronic device needs to be taken out from the waterproof casing 1 before it can be operated, which is inconvenient to the user.

### SUMMARY OF THE INVENTION

Therefore, an object of the invention is to provide a waterproof casing that permits operation of an electronic device accommodated therein under water.

Accordingly, the waterproof casing of the invention is adapted for enclosing an electronic device therein. The electronic device includes at least one operating portion. The waterproof casing comprises casing unit and at least one pliable transparent film. The casing unit is formed with at least one opening that is adapted to correspond in position and size to the operating portion of the electronic device and that has a peripheral edge. The pliable transparent film corresponds in number to the at least one opening and is connected to the peripheral edge of the at least one opening.

In some embodiments, the film has a thickness ranging from about 0.1 mm to about 02 mm.

In some embodiments, the casing unit includes a first casing half and a second casing half that are coupled together and that cooperatively define an internal receiving space adapted for accommodating the electronic device. The first and second casing halves are formed from a rigid material.

In some embodiments, at least one of the first and second casing halves is recessed at a junction therebetween so that the first and second casing halves cooperatively form an annular groove, and the waterproof casing further comprises an annular waterproofing strip. The waterproofing strip is received in the groove and is fittingly disposed between the first and second casing halves.

In some embodiments, the waterproofing strip has a cross-sectional area slightly larger than that of the groove.

In some embodiments, the first casing half is a flat plate. The second casing half includes a base wall spaced apart from the first casing half, and a surrounding wall extending from the base wall toward the first casing half.

In some embodiments, the surrounding wall of the second casing half has an end edge which is proximate to the first casing half and which is formed with a plurality of screw holes extending toward the base wall. The first casing half is formed with a plurality of through holes corresponding to the screw holes for passage of a plurality of bolts therethrough to engage the screw holes so as to fasten the first casing half to the second casing half.

In some embodiments, the base wall of the second casing half is formed with one opening, and the surrounding wall of the second casing half is formed with a plurality of the openings.

In some embodiments, the groove is formed in the end edge of the surrounding wall of the second casing half that is proximate to the first casing half.

In some embodiments, the film is adhered to the peripheral edge of the opening using a waterproofing adhesive.

In some embodiments, the film is secured to the peripheral edge of the opening using high frequency welding.

The meritorious effects of the waterproof casing according to the invention reside in that, with the arrangement of the openings in the casing unit to correspond in position and size to the operating portions of the electronic device, and with the provision of the pliable transparent films that are connected to the peripheral edges of the openings, a user is permitted to operate the operating portions through the films, thereby achieving the object of operating the electronic device accommodated within the waterproof casing under water.

### BRIEF DESCRIPTION OF THE DRAWINGS

Other features and advantages of the present invention will become apparent in the following detailed description of the preferred embodiment with reference to the accompanying drawings, of which:

FIG. 1 is an exploded perspective view of a conventional waterproof casing;

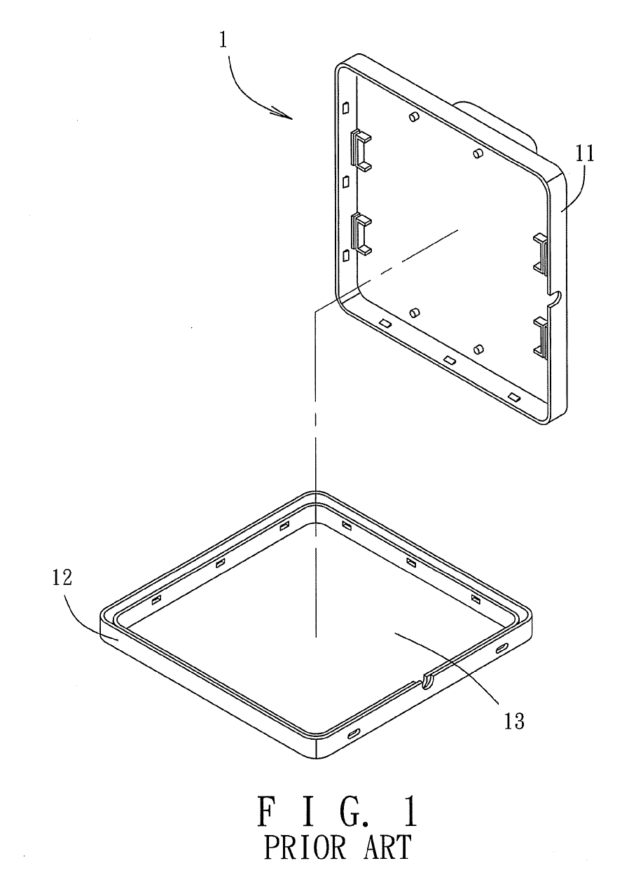

FIG. 2 is a perspective view to illustrate an embodiment of a waterproof casing;

FIG. 3 is an exploded perspective view to illustrate an embodiment of the invention and an electronic device; and

FIG. 4 is a sectional view to illustrate the assembly relationship between an embodiment of the invention and the electronic device.

### DETAILED DESCRIPTION

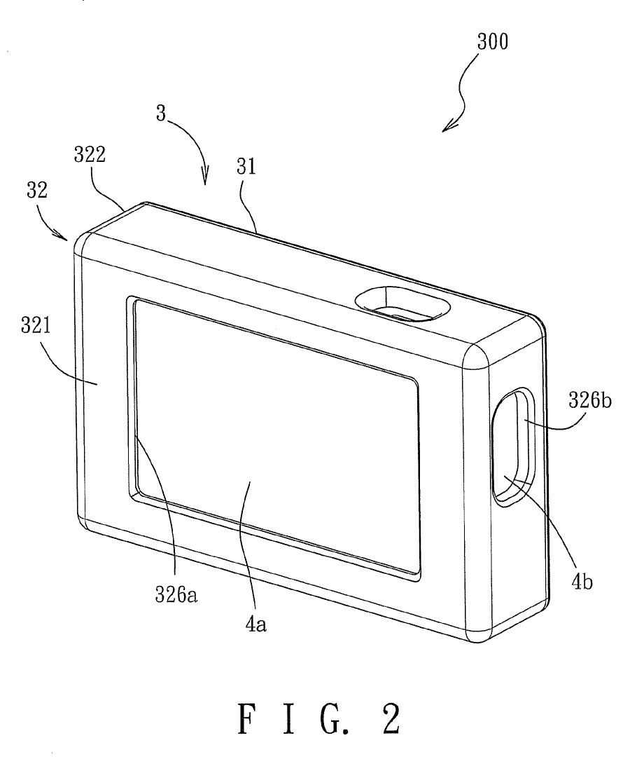

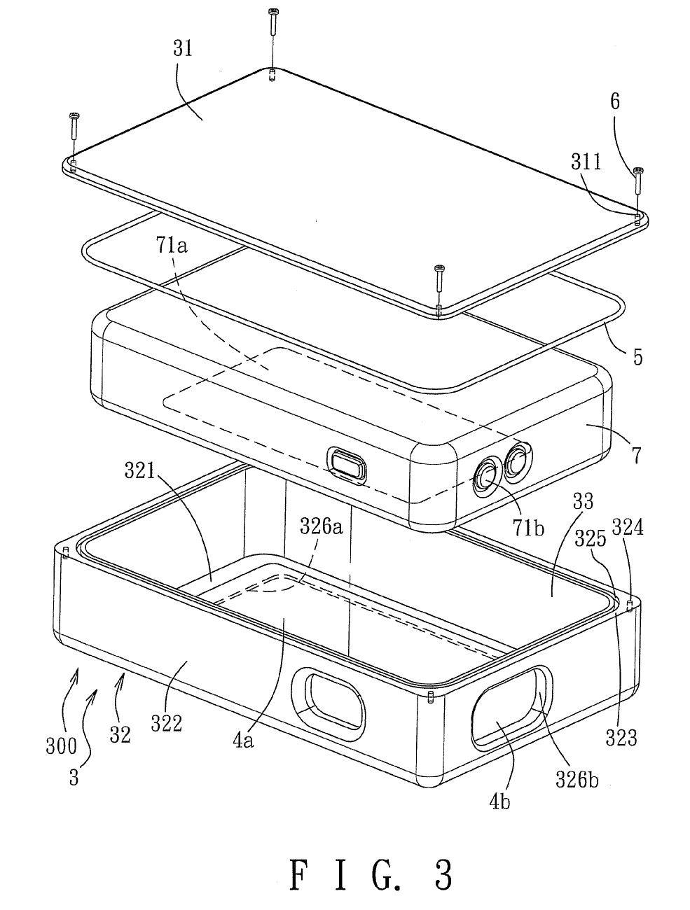

Referring to FIGS. 2 and 3, an embodiment of a waterproof casing 300 is adapted for use with an electronic device 7 to sealingly enclose the electronic device 7 therein. In this embodiment, the electronic device 7 is exemplified to include an operating portion 71a in the form of a touch screen, and a plurality of operating portions 71b in the form of buttons. The waterproof casing 300 includes a casing unit 3, a plurality of pliable transparent films 4a, 4b, a waterproofing strip 5, and a plurality of bolts 6.

The casing unit 3 includes a first casing half 31 and a second casing half 32 that are coupled together and that cooperatively define an internal receiving space 33 for accommodating the electronic device 7. The first and second casing halves 31, 32 are formed from a rigid material. The first casing half 31 is a flat plate. The second casing half 32 includes a base wall 321 spaced apart from the first casing half 31, and a surrounding wall 322 extending from the base wall 321 toward the first casing half 31.

The surrounding wall 322 of the second casing half 32 has an end face 323 formed with an annular groove 325. In this embodiment, the groove 325 is formed in the second casing half 32. In other embodiments, the groove 325 may be formed in the first casing half 31, or at a junction between the first and second casing halves 31, 32 (i.e., partly formed in the first casing half 31 and partly formed in the second casing half 32). The waterproofing strip 5 is annular in shape, and is received in the groove 325. The waterproofing strip 5 has a cross-sectional area slightly larger than that of the groove 325.

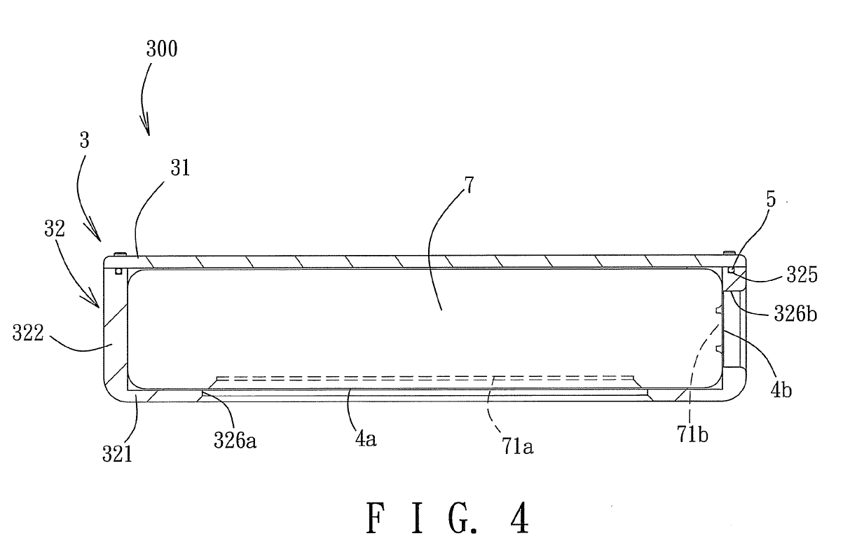

Referring to FIGS. 3 and 4, in this embodiment, an end edge of the surrounding wall 322 of the second casing half 32 that is proximate to the first casing half 31 is formed with a plurality of screw holes 324 extending toward the base wall 321. The first casing half 31 is formed with a plurality of through holes 311 corresponding respectively to the screw holes 324. The bolts 6 are extended respectively through the through holes 311 to engage the screw holes 324, respectively, so as to fasten the first casing half 31 to the second casing half 32.

The base wall 321 of the second casing half 32 is formed with an opening 326a corresponding in position and size to the operating portion 71a. The surrounding wall 322 of the second casing half 32 is formed with a plurality of openings 326b corresponding in position and size to the operating portions 71b, respectively. The films 4a, 4b are respectively adhered to peripheral edges of the openings 326a, 326b using a waterproofing adhesive.

In this embodiment, although the films 4a, 4b are adhered Lo the peripheral edges of the openings 326a, 326b using a waterproofing adhesive, the manner of connecting the films 4a, 4b to the peripheral edges of the openings 326a, 326b is not limited to what is disclosed herein. The films 4a, 4b may be secured to the peripheral edges of the openings 326a, 326b using high frequency welding, or any other waterproof bonding techniques.

If the electronic device 7 is intended to be operated under water, the electronic device 7 is first placed inside the second casing half 32, and the waterproofing strip 5 is fitted into the groove 325, followed by coupling of the first casing half 31 to the second casing half 32. The bolts 6 are then fastened in place so that the waterproofing strip 5 is fittingly disposed between the first and second casing halves 31, 32, thereby providing a waterproofing effect. At this time, the operating portions 71a, 71b of the electronic device 7 are located at positions corresponding to the openings 326a, 326b, respectively.

Since the films 4a, 4b are formed from a transparent material, the user can see the operating portions 71a, 71b of the electronic device 7 through the films 4a, 4b. Moreover, since the films 4a, 4b are formed from a pliable material with a thickness of about 0.1 mm to about 0.2 mm, the user can press the operating portions 71a, 71b through the films 4a, 4b.

It is noted that, even if the operating portion 71 a is a touch screen as exemplified herein, with the use of the film 4a, a good pressing effect can still be achieved, and there will not be the problem of ineffective pressing.

In sum, by providing the openings 326a, 326b in the casing unit 3 to correspond in size and position to the operating portions 71a, 71b of the electronic device 7, and by providing the pliable transparent films 4a, 4b that are connected to the peripheral edges of the openings 326a, 326b, the user can press the operating portion 71 a (i.e., touch screen) and the operating portions 71b (i.e., buttons) of the electronic device 7 through the films 4a, 4b when under water, thereby rendering operation of the electronic device 7 accommodated within the waterproof casing 300 from the outside possible and thereby overcoming the problems associated with the aforementioned prior art.

While the present invention has been described in connection with what is considered the most practical and preferred embodiment, it is understood that this invention is not limited to the disclosed embodiment but is intended to cover various arrangements included within the spirit and scope of the broadest interpretation so as to encompass all such modifications and equivalent arrangements.

What is claimed is:

1. A waterproof casing adapted to enclose an electronic device therein, the electronic device including at least one operating portion, said waterproof casing comprising:
a casing unit formed with at least one opening that is adapted to correspond in position and size to the operating portion of the electronic device and that has a peripheral edge; and
at least one pliable transparent film that corresponds in number to said at least one opening and that is connected to said peripheral edge of said at least one opening.

2. The waterproof casing according to claim 1, wherein said film has a thickness ranging from about 0.1 mm to about 0.2 mm.

3. The waterproof casing according to claim 2, wherein said casing unit includes a first casing half and a second casing half that are coupled together and that cooperatively define an internal receiving space adapted for accommodating the electronic device, said first and second casing halves being formed from a rigid material.

4. The waterproof casing according to claim 3, wherein at least one of said first and second casing halves is recessed at a junction therebetween so that said first and second casing halves cooperatively form an annular groove, said waterproof casing further comprising an annular waterproofing strip, said waterproofing strip being received in said groove and being fittingly disposed between said first and second casing halves.

5. The waterproof casing according to claim 4, wherein said waterproofing strip has a cross-sectional area slightly larger than that of said groove.

6. The waterproof casing according to claim 4, wherein said first casing half is a flat plate, and said second casing half includes a base wall spaced apart from said first casing half, and a surrounding wall extending from said base wall toward said first casing half.

7. The waterproof casing according to claim 6, wherein said surrounding wall of said second casing half has an end edge which is proximate to said first casing half and which is formed with a plurality of screw holes extending toward said base wall, said first casing half being formed with a plurality of through holes corresponding to said screw holes for passage of a plurality of bolts therethrough to engage said screw holes so as to fasten said first casing half to said second casing half.

8. The waterproof casing according to claim 6, wherein said base wall of said second casing half is formed with one said opening, and said surrounding wall of said second casing half is formed with a plurality of said openings.

9. The waterproof casing according to claim 6, wherein said groove is formed in said end edge of said surrounding wall of said second casing half that is proximate to said first casing half.

10. The waterproof casing according to claim 6, wherein said film is adhered to said peripheral edge of said opening using a waterproofing adhesive.

11. The waterproof casing according to claim 6, wherein said film is secured to said peripheral edge of said opening using high frequency welding.

12. The waterproof casing according to claim 1, wherein said film is adhered to said peripheral edge of said opening using a waterproofing adhesive.

13. The waterproof casing according to claim 1, wherein said film is secured to said peripheral edge of said opening using high frequency welding.
